(19) United States
(12) Patent Application Publication
(10) Pub. No.: US 2026/0023113 A1
(43) Pub. Date: Jan. 22, 2026

(54) SYSTEM AND METHODS FOR CRITICAL PATH TRACKING SYSTEM-ON-CHIP

(71) Applicant: MaxLinear, Inc., Carlsbad, CA (US)

(72) Inventors: Arun Kedambadi, Carlsbad, CA (US); Vamsi K. Paidi, Irvine, CA (US); Ingo Volkening, Singapore (SG); Prakash B. Chintamaneni, Ladera Ranch, CA (US)

(73) Assignee: MaxLinear, Inc., Carlsbad, CA (US)

(21) Appl. No.: 19/277,317

(22) Filed: Jul. 22, 2025

Related U.S. Application Data
(60) Provisional application No. 63/674,270, filed on Jul. 22, 2024.

(51) Int. Cl. G01R 31/317; G04F 10/00

(52) U.S. Cl. CPC G01R 31/31708; G01R 31/31725; G04F 10/005

(57) ABSTRACT

For critical path monitoring in an integrated circuit (IC), a system includes a data flip-flop configured to receive a data input and a clock input, and generate a first data output and a first clock output. A data delay path generates a delayed data output. An output flip-flop, coupled to the data delay path generates a second data output and a second clock output. A time-to-digital converter (TDC), coupled to the data delay path, includes a comparator bank that compares the delayed data output against reference levels and generates a code. An encoder, coupled to the comparator bank converts the code into a binary code representing the time delay. A minimum delay search coupled to the TDC includes a control circuit, configured to dynamically adjust the supply voltage and other parameters of the IC based on the timing margins and delay settings identified by the minimum delay search.

### RELATED APPLICATION

This application claims the benefit of U.S. Provisional Application No. 63/674,270, filed Jul. 22, 2024, the disclosure of which is incorporated herein by reference in its entirety.

The examples discussed in the present disclosure are related to critical path tracking.

### BACKGROUND

Unless otherwise indicated herein, the materials described herein are not prior art to the claims in the present application and are not admitted to be prior art by inclusion in this section.

In the field of integrated circuit (IC) design, ensuring optimal performance of critical paths in the IC while minimizing power consumption is a persistent challenge. The critical paths are the longest signal paths through the IC, which determine the maximum speed at which the circuit can operate. Some methods for achieving such balance often involve the use of ring oscillators or other benchmark circuits to measure the speed of a device and adjust the supply voltage accordingly. However, such methods present several significant limitations that prevent achieving optimal results.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

Accordingly, some examples described herein include a critical path tracking system for an integrated circuit (IC). The system includes a data input and clock input feeding a real critical path comprising a first set of combinatorial logic receiving the data input and clock input, and generating a first output. An output flip-flop is coupled to the data delay path to receive the delayed data output and the first clock output, and generate a second data output and a second clock output. In some examples, a time-to-digital converter (TDC) is coupled to the data delay path and includes a comparator bank, configured to compare the delayed data output against reference levels and generate a code.

In some examples, a minimum delay search, coupled to TDC includes a search algorithm, configured to iteratively adjust the delay introduced by the data delay path and monitor the timing margins to identify the least delay that meets timing margins. In some examples, a control circuit, coupled to the minimum delay search, dynamically adjusts the supply voltage and other parameters of the IC based on the timing margins and delay settings identified by the minimum delay search. In some examples, a software loop, reads the output from the minimum delay search, analyzes the timing margins, and controls the control circuit to maintain optimal performance and power consumption of the IC.

Some examples include a method for critical path tracking. The method includes providing a TDC with a first precision level. The method continues by receiving output data from a critical path within the IC and processing the output data through a softmax function to generate softmax outputs. In some examples, the method includes analyzing the softmax outputs to determine a proximity to a predefined threshold and determining, based on the proximity to the threshold, when the current precision level is sufficient. The method includes adjusting the precision level when the softmax outputs indicate that the current precision level is insufficient and maintaining the first precision level when the softmax outputs indicate that the current precision level is sufficient.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is noted, however, that the appended drawings illustrate only some aspects of this disclosure and the disclosure may admit to other equally effective examples.

To facilitate understanding, identical reference numerals have been used, where possible, to designate identical elements that are common to the figures. It is contemplated that elements and features of one example may be beneficially incorporated in other examples without further recitation.

FIG. 1A illustrates a schematic of an exemplary critical path tracking system, in accordance with some examples;

FIG. 1B illustrates a schematic of an exemplary critical path tracking system, in accordance with some examples;

FIGS. 2A-2B illustrate a timing diagram for an operation of the exemplary critical path tracking system shown in FIGS. 1A-1B, in accordance with some examples; and

FIGS. 3A-3B illustrates a schematic of an exemplary critical path tracking system, in accordance with some examples;

FIG. 4 depicts a flowchart depicting a method of operation for the exemplary critical path tracking system shown in in FIG. 3 in accordance with some examples.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single example, but other examples are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure.

As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs). As used herein, “directly coupled” means that two elements are directly in contact with each other. As used herein, “fixedly coupled” or “fixed” means that two components are coupled so as to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them. As utilized herein, “substantially” means that any difference is negligible, or that such differences are within an operating tolerance that are known to persons of ordinary skill in the art and provide for the desired performance and outcomes as described in one or more examples herein. Descriptions of numerical ranges are endpoints inclusive.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

Examples described as being implemented in hardware should not be limited thereto, but can include examples implemented in software, or combinations of software and hardware, and vice-versa, as will be apparent to those skilled in the art, unless otherwise specified herein. In the exemplary examples described herein, an example showing a singular component should not be considered limiting; rather, the invention is intended to encompass other examples including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

A ring oscillator may be used to measure the speed of a device and adjust the supply voltage accordingly. A ring oscillator may include an odd number of inverters connected in a loop, with the frequency of oscillation providing an indication of the IC's operational speed. This method does not accurately represent the real critical paths within an application specific integrated circuit (ASIC). Therefore, adjustments based on ring oscillators may not reflect operational limits, leading to suboptimal performance and unnecessary power consumption.

Many solutions lack flexibility and adaptability to changes in process, voltage, and temperature (PVT) conditions. The static nature of these hardware-centric methods prevents dynamic responses to varying operational conditions. Additionally, the one-size-fits-all approach does not account for the variability in individual ICs, as chips may exhibit different characteristics due to manufacturing variations. Such uniform approach may fail to result in optimal power consumption, which is increasingly useful in modern electronics.

The examples described herein may provide a robust and adaptable solution for optimizing IC performance and power consumption via a critical path tracking and dynamic voltage scaling circuit. By accurately monitoring and adjusting critical paths in an ASIC system on chip (SoC), the examples herein may ensure that the IC operates within safe margins while minimizing power usage. Accordingly, the examples herein may provide a system, method, and apparatus for real-time monitoring of critical timing paths in ASICs and dynamically adjusting the supply voltage to optimize performance and power consumption.

While many solutions implement a “one-size-fits-all” approach, such solutions do not account for the variability in individual ICs. For example, ASICs may exhibit different characteristics due to manufacturing variations, which makes a uniform approach less effective. Moreover, many solutions provide inadequate margin monitoring. Effective monitoring of timing margins may prevent timing violations that may lead to errant behavior and functional failures. Many approaches do not provide a precise and continuous measurement of the remaining timing margin, which may facilitate reliable operation. Accordingly, the examples herein set forth a critical path circuit that provides real-time monitoring and adjustment of critical timing paths within an ASIC.

Some examples described below include a circuit that may monitor actual critical paths and simulated (i.e., replicated) critical paths. Such dual capability may allow for testing and validation of the system under various conditions. Some examples include multiple capture flops that may record delayed versions of the signal captured by no-delay flops. By comparing these delayed captures with the no-delay capture, the system may accurately measure the remaining timing margin. In some examples, based on the measured margin, the system, apparatus, and/or method may dynamically adjust the supply voltage for optimal performance. Such dynamic adjustment may be made in real-time, allowing the system to respond to changes in PVT conditions and operational requests.

Unlike hardware-centric solutions, some examples may use a software loop to analyze the captured data and make voltage adjustments. Such an approach may offer greater flexibility, allowing for dynamic changes in monitoring parameters and more precise control over the IC's operation. Some examples may provide in-situ monitoring capabilities, which may allow for real-time observation of the critical path's performance. Such a feature may provide that the adjustments made are based on accurate and current operational data, enhancing the reliability and efficiency of the system.

In some examples, a TDC-based approach may be implemented for critical path monitoring. Such method may use high-resolution TDCs to directly measure timing margins with precise granularity. By implementing TDCs across various sections of the IC, the system may monitor real-time data activity, providing an accurate representation of the IC's operational conditions. Such implementation enables dynamic adjustments of the supply voltage, ensuring optimal performance and power efficiency.

For example, the TDC-based approach offers improved visibility into the IC's performance by measuring actual data activity rather than relying on synthetic benchmarks. High-resolution TDCs may resolve delays to within a few picoseconds, making such TDCs suitable for high-speed analog and mixed-signal circuits where precise timing control is useful. Furthermore, the distributed placement of compact TDCs across the IC allows for monitoring, accommodating the variability of different IC sections.

As discussed in detail below, such exemplary implementations addresses the limitations of previous methods by providing flexibility, adaptability, and precise control over timing margins and power consumption. By dynamically adjusting the supply voltage based on real-time data, the TDC-based system corresponding to some examples herein allows the IC to operate at optimal efficiency under varying operational conditions, enhancing the reliability and performance of modern semiconductor devices.

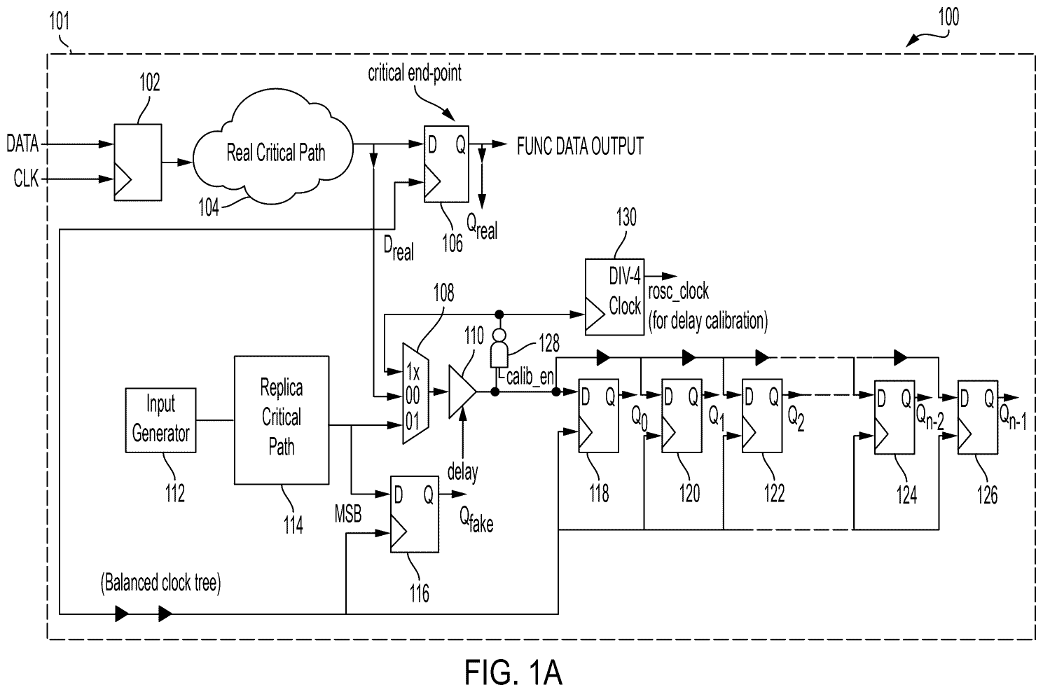

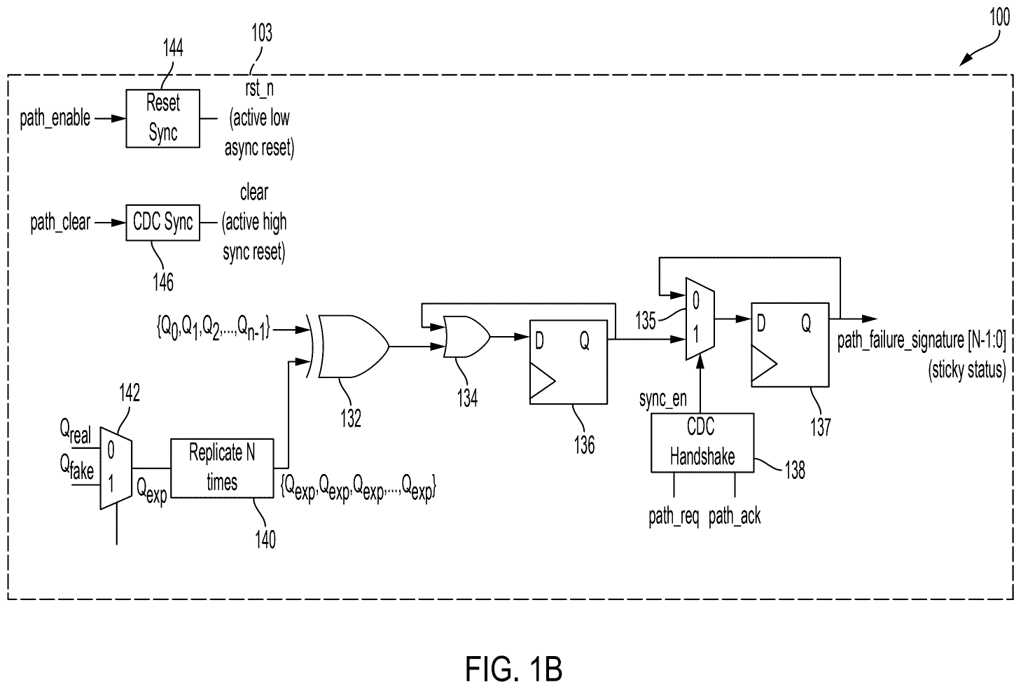

FIGS. 1A-1B illustrate an exemplary critical path tracking system-on-chip 100 (“system 100”). In some examples, system 100, may include two circuits 101, 103 (FIG. 1A, FIG. 1B, respectively), which may have distinct and complementary functions. Circuit 101 may monitor the critical timing paths and capture relevant data, while circuit 103 may process this data, may generate path failure signatures, and may facilitate synchronization across system 100. Circuits 101, 103 may provide real-time monitoring and dynamic adjustment of an integrated circuit's performance.

As shown in FIG. 1A, in some examples, circuit 101 may include multiplexer (MUX) 102, real critical path 104, capture flip-flop 106, multiplexer 108, programmable delay element 110, input generator 112, replica critical path 114, capture flip-flop (CFF) 116, CFF (Q0) 118, CFF (Q1) 120, CFF (Q2) 122, CFF (Qn-2) 124, CFF (Qn-1) 126, NAND gate 128, and/or clock divider 130. Circuit 101 may capture data from critical timing paths and introduce delays to measure timing margins. Such operation may include monitoring real and replica paths and generating detailed timing data.

In some examples, system 100's tracking circuit may include multiplexer 108 that may select between real critical path 104 and replica critical path 114. In some examples, real critical path 104 is monitored by CFF 106, which may record the output data (Q_real) and the timing signal (D_real). Multiplexer 108 may route different signals to the programmable delay element 110. Programmable delay element 110 may introduce controlled timing shifts, allowing system 100 to simulate various timing conditions.

In some examples, input generator 112 may feed signals into replica critical path 114, so that replica critical path 114 may mimic the real critical path 104 accurately, which may be used for calibration. In some examples, replica critical path 114 may direct a signal to a CFF 116 that may capture the most significant bit (MSB) of the delayed signal (e.g., Q_fake). To facilitate calibration, NAND gate 128 may combine the calibration enable signal (calib_en) with other control signals, and clock divider 130 may generate a divided clock signal (e.g., rosc_clock) used for delay calibration. In some examples, clock divider 130 may include one or more ring oscillators, phase-lock-loops, and/or digital crystals.

In some examples, CFFs 118, 120, 122, 124, 126 may be used to record progressively delayed versions of the signal, shown in FIG. 1 as Q₀, Q₁, Q₂, Qₙ₋₂, and Qₙ₋₁, respectively. CFFs 118, 120, 122, 124, 126 may provide a view of how delays affect the critical path performance, which may provide precise measurement of timing margins so that the IC may operate within optimal parameters.

Input Data (DATA) and Clock (CLK) inputs may provide data and clock signals used for the operation of the critical path circuit. The data and clock inputs may synchronize the timing paths within the IC. Multiplexer MUX 102 may select between the real critical path 104 and the replica critical path 114 based on the operational mode for monitoring and calibration purposes. Output Data (FUNC DATA OUTPUT) may be the output for the circuit 101 and may be the functional data adjusted for optimal timing.

Real critical path 104 may be the longest signal path through the exemplary IC, which may determine the maximum operational speed of the circuit. Monitoring the real critical path 104 may allow the IC to meet its timing limits. In some examples, capture flip-flop 106 may be positioned at the end of the real critical path 104 to capture the output data (Q_real) and the timing signal (D_real). Capture flip-flop 106 may assess the timing margins by comparing the captured data with delayed data.

In some examples, replica critical path 114 may mimic the real critical path 104 for calibration and testing purposes. Replica critical path 114 may allow system 100 to simulate real critical path 104 conditions without affecting the actual signal path, providing a safe way to measure and adjust timing margins. Input generator 112 may generate the input signals for the replica critical path. The input generator signal may be one or more of a deterministic signal or a random signal based on the replica critical path 114. For example, when the real critical path 104 includes a digital finite impulse response (FIR) filter, the replica critical path 114 may include a pseudo filter and the input generator may generate a random signal to the filter. The random signal may be a random sequence, such as a pseudo-random binary sequence (PRBS). Input generator 112 provides that the replica path may operate under similar conditions as the real critical path, facilitating accurate calibration.

In some examples, CFF 116 may capture the MSB of the delayed signal (Q_fake) from the replica critical path 114 to determine the timing accuracy of the replica critical path 114 compared to the real critical path 104.

Multiplexer 108 may select between different inputs (e.g., 1x, 00, 01) for the subsequent flip-flops. Multiplexer 108 may allow the circuit to route different signals based on current calibration or monitoring. In some examples, programmable delay element 110 may introduce controlled timing shifts in the signal path, allowing system 100 to create precise timing margins. Programmable delay element 110 may simulate different timing conditions and assess system 100's performance under various delays.

In some examples, NAND gate 128 may combine the calibration enable signal (calib_en) with the other control signals, facilitating the switching to different modes. In some examples, system 100 may operate in three distinct mode. Such modes include programmable delay calibration mode, real critical path tracking mode, and replica critical path tracking mode.

In programmable delay calibration mode, the programmable delay element 110 may have a ring-oscillator setup to measure and calibrate the delay accurately. Calibration mode may be used for initial calibration of the programmable delay in the system 100 to provide precise timing adjustments. In the real critical path tracking mode, system 100 may monitor the timing failure points in a real critical path 104. Based on the observed data, the supply voltage may be increased or decreased to maintain optimal performance and reliability, for example, via dynamic voltage scaling (DVS).

For example, real critical path tracking mode may include, in some examples, initializing the control signals by setting path_enable=0, path_sel=0, and configuring the delay (delay [6:0]=<desired_value>). System 100 may enable the path by setting path_enable=1 and observing the path failure signature for the failure signature position. When a supply adjustment is made, system 100 may disable the path (path_enable=0) and may reprogram the supply change using pulse width modulation (PWM) or inter-integrated circuit power management integrated circuit (I2C-PMIC). System 100 may repeat the process by adjusting the delay (delay [6:0]) according to the tracking algorithm.

System 100 may include a replica critical path tracking mode, which may be similar to the real critical path tracking mode but operate on a fake or replica critical path 114. Replica critical path tracking mode may be useful for scenarios in which the real critical path 104 may not be monitored directly, allowing safe and accurate measurements without interfering with the actual operation. For example, replica critical path tracking mode may initialize the control signals by setting path_enable=0, path_sel=1, and configuring the delay (delay [6:0]=<desired_value>). Enabling the path by setting path_enable=1 and observing the path failure signature for the desired failure signature position. When a supply adjustment is made, PWM or I2C-PMIC may be used to disable the path (path_enable=0) and/or reprogram the supply change. The process may be repeated by adjusting the delay (delay [6:0]) according to the tracking algorithm.

In some examples, NAND gate 128 may activate the delay calibration. For example, clock Divider 130 (DIV-4 Clock) may generate a divided clock signal (rosc_clock) used for delay calibration. By dividing the clock frequency, clock divider 130 may provide a timing reference for calibrating programmable delay element 110. CFFs 118, 120, 122, 124, 126 (Q0 to Qn-1, respectively) may capture the delayed versions of the signal at different stages. Individual flip-flops may record a progressively delayed signal, allowing system 100 to measure the timing margin by comparing the outputs. The sequence of captured signals may provide a view of how the delay affects real critical path 104 performance.

As shown in FIG. 1B, circuit 103 adds synchronization, replication, and/or failure detection functionalities. Circuit 103 may process captured data to generate path failure signatures and allow synchronization across different parts of the circuit 103. Circuit 103 combines, selects, and/or stores signals to provide a comprehensive status of the timing paths, which may be used by the software loop for dynamic adjustments.

Reset sync 144 and clock domain crossing (CDC) sync 146 components allow initialization and clearing of the circuit. XOR gate 132 and D flip-flop 137 may generate and store the path failure signature, indicating timing defects in real critical path 104. The CDC handshake 138 may facilitate reliable communication across different clock domains, while the Replicate N Times 140 and multiplexer 142 components may manage the replication and routing of signals for comprehensive monitoring. These components may enhance the circuit's ability to monitor and adjust the timing paths within an IC, ensuring optimal performance and reliability.

In some examples, reset sync 144 may synchronize the reset signal (path_enable) with the system clock. Reset sync 144 may generate an active low asynchronous reset signal (rst_n) that may initialize or reset system 100. CDC Sync 146 (Clock Domain Crossing) may synchronize the path_clear signal with the system clock, generating an active high synchronous reset signal (clear), which may be used for clearing the status registers or counters in the circuit.

In some examples, XOR gate 132 may combine the outputs of the CFFs (e.g., Q0, Q1, Q2 . . . , Qn-1) to generate a combined signal indicating the overall status of the captured data. In some examples, XOR gate 132 may identify when the flip-flops have captured the expected data correctly. The signal from the XOR gate 132 may be directed to the OR gate 134. The OR gate 134 may receive the output of the D flip flop 136. By directing the signal from the XOR gate 132 and the output of the D flip flop 136 to the OR gate 134, the stability of the signal from XOR gate 132 may be enhanced to prevent signal jitter.

In some examples, multiplexer 135 may select between the combined signal from gate D flip flop 136 and the output of the D flip-flop 137. The selection may be based on the state of the sync_enable signal, which may determine whether the circuit is in synchronization mode. D Flip-Flop 137 may store the selected signal from multiplexer 135 and provide a stable output (path_failure_signature). The output represents the sticky status of the path failure signature, indicating any timing failures in real critical path 104.

CDC handshake 138 may manage the communication between different clock domains, ensuring reliable data transfer. CDC handshake 138 may generate synchronization signals (e.g., sync_en, path_req, and path_ack) to coordinate the timing and status updates across the circuit. In some examples, replicate N Times 140 may replicate the input signal (Q_exp) N times to generate a set of replicated signals (Q_exp, Q_exp . . . , Q_exp). Such replication may create multiple instances of the signal for monitoring and analysis.

In some examples, multiplexer 142 may select between the replicated signals generated by the Replicate N Times 140 and the initial input signal (e.g., e.g., Q0, Q1, Q2 . . . , Qn-1). Such selection may aid in routing the appropriate signal for further processing and analysis within the circuit. Path failure signature (path_failure_signature) output may be a sticky status register that may hold the failure status of real critical path 104. The path failure signature output may provide an indication of timing failures detected during the monitoring process.

### Delayed Capture Functionality

Delayed capture functionality may facilitate precise measurement and analysis of timing margins. Such functionality involves the use of no-delay flip-flops and delayed capture flip-flops to monitor the timing of signals traversing the critical paths (e.g., 104, 114) within the IC. The comparisons between the captured data from these flip-flops may provide timing margins used for DVS and overall system reliability.

No-delay flip-flops (e.g., CFF 106) may capture the state of signals at specific points along the critical path without introducing an intentional delay. Such flip-flops may provide a baseline measurement of the signal timing as it propagates through the circuit. CFF 106 for example, may be positioned at the end of the real critical path 104 to capture the output data (Q_real) and timing signal (D_real). CFF 106 may provide a measurement of the critical path timing under operating conditions. In contrast, CFFs 118, 120, 122, 124, 126 may capture the state of the signal at various points along the critical path. CFFs 118, 120, 122, 124, 126 may provide a snapshot of the signal timing, serving as reference points for comparing with delayed captures. These delayed capture flip-flops may introduce intentional delays into the signal path before capturing the state of the signal. These delays may be introduced using a programmable delay element 110 that may be adjusted to simulate different timing conditions. The delayed capture provides the effect of various delays on signal timing to quantify timing margins.

For example, in some examples, programmable delay element 110 may introduce controlled delays into the signal path, allowing for precise adjustment of the timing conditions. By varying the delay, system 100 may observe the effects on signal propagation and capture timing. Delayed capture flip-flops (e.g., CFFs 118, 120, 122, 124, 126), in addition to their role in no-delay capture, may also record the state of the signal after the signal has been delayed. Such dual functionality enables the system to compare no-delay and delayed captures effectively.

In some examples, system 100 may include a method for delay capture. The method may include initialization in which the system 100 may initialize the programmable delay element 110 to a specific delay setting. This setting may be dynamically adjusted to simulate different timing conditions. Input signals (DATA and CLK) may propagate through the real critical path 104 and the replica critical path 114. The signals may be monitored at various points along these paths. No-delay flip-flops (e.g., CFFs 118, 120, 122, 124, 126) may record the state of the signals at specific points without any additional delay. These captures may provide a baseline measurement of the signal timing. Next, programmable delay element (110) may introduce controlled delays into the signal path. The delayed capture flip-flops may record the state of the signals after the delay has been applied._Flip-flops may capture a progressively delayed version of the signal, providing a detailed view of how delays affect the timing.

The data from the no-delay and delayed captures may be compared to quantify the timing margins. The comparison involves analyzing the differences in the signal states recorded by the flip-flops. For example, in some examples, XOR gate 132 processes the captured data, generating a signal that may indicate the overall status of the timing margins. This processed signal may be stored in the D flip-flop 137, creating a path failure signature.

System 100 software loop may read the path failure signature and the captured data from the flip-flops. System 100 may analyze the timing margins to determine when there are timing violations. Based on the analysis, system 100 software may determine whether to adjust the supply voltage or recalibrate the programmable delays. When the timing margins are tight (e.g., exceeding, or nearing a threshold margin), the software may increase the supply voltage to ensure reliable operation. Conversely, when the margins are ample, the software may decrease the voltage to save power. Thus, system 100 software may send control signals to adjust the voltage regulators and the programmable delay element, dynamically optimizing the IC's performance and power consumption.

System 100 software may interpret margin data captured by the flip-flops and optimize the IC's operation. System 100 may monitor the timing margins and react to changes by adjusting the supply voltage and delay settings. For example, system 100 software may periodically read the captured data from the no-delay and delayed capture flip-flops and also retrieves the path failure signature from the D flip-flop 136.

System 100 software may analyze the timing margins by comparing the no-delay and delayed captures. In some examples, system 100 may determine the slack or deficit in the timing, identifying any potential issues that may affect performance. Based on such analysis, system 100 software may determine the necessary adjustments to the supply voltage and delay settings and maintain optimal performance while minimizing power consumption.

In some examples, system 100 software may send control signals to the voltage regulators, adjusting the supply voltage dynamically based on the current timing margins. System 100 software may also reconfigure the programmable delay element 110 to fine-tune the timing conditions so that the IC operates within safe and efficient parameters. The software loop may monitor the critical path performance, reacting to any changes in real-time. This ongoing process allows the IC to adapt to varying operational conditions, such as changes in workload, temperature, and process variations.

Thus, the no-delay vs. delayed capture functionality, as described in FIG. 1A and FIG. 1B, may provide a mechanism for real-time monitoring and analysis of timing margins within an integrated circuit. By using no-delay and delayed captures, the system may accurately quantify timing margins and make dynamic adjustments to optimize performance and power consumption. The software may interpret the captured data and implement adjustments to maintain the IC's reliability and efficiency. This robust monitoring and adjustment capability allows the IC to operate at optimal performance under varying conditions, enhancing its overall reliability and efficiency.

### DVS in Critical Path Circuit

In some examples, system 100 may implement DVS, allowing system 100 to adjust the supply voltage in real-time based on the current performance and timing. Such DVS functionality in the described circuits 101, 103 may use real-time measurements of timing margins to dynamically optimize power consumption without compromising the performance or reliability of the IC. By dynamically adjusting the supply voltage, system 100 may allow the IC to operate within safe and efficient parameters, balancing power savings with performance and reliability. The interplay between hardware components (such as programmable delay elements and capture flip-flops) and software control loops may facilitate voltage scaling, enhancing the overall efficiency and effectiveness of the integrated circuit.

### Real-Time Measurement of Timing Margins

DVS functionality may measure timing margins within the critical paths of the IC in real time. As shown in FIG. 1A, circuit 101 may include components such as the capture flip-flops 118, 120, 122, 124, 126, programmable delay element 110, and real critical path 104 and replica critical path 114. These components may monitor the timing margins dynamically. The capture flip-flops (e.g., 118, 120, 122, 124, 126) may record the timing information of signals traversing the critical paths, and programmable delay element 110 may introduce controlled delays to simulate different operational conditions.

The data captured by capture flip-flops (e.g., 118, 120, 122, 124, 126) may be processed to determine the timing margins, which may indicate the slack or deficit in timing for signals to propagate through real critical path 104. Such timing information may provide DVS with a real-time snapshot of system 100's performance under current conditions.

### Dynamic Adjustment of Supply Voltage

In some examples, based on the measured timing margins, the DVS mechanism may dynamically adjust the supply voltage to optimize power consumption. Such dynamic adjustment process may involve hardware and software loop components to ensure precise control and responsiveness.

For example, programmable delay element 110 may introduce delays to measure timing margins accurately and provide data for determining voltage adjustments. CFFs 118, 120, 122, 124, 126 may capture the state of the signal at various points along the real critical path 104 and provide data on how delays affect the critical path performance. Clock Divider 130 may generate the clock signals for delay calibration and timing measurement. CDC handshake 138 and sync components (e.g., reset sync 144 and CDC sync 146) may provide reliable communication and synchronization across different clock domains and maintain the integrity of timing data used for voltage scaling.

In some examples, system 100's software loop may read the timing margin data from the hardware components, process timing margin data, and make determinations regarding the supply voltage adjustments. In some examples, system 100 may include a method for reading timing margin data including: data acquisition in which the software may read the timing data captured by the flip-flops and process the data to calculate the current timing margins. The software may analyze the timing margins to determine when the current supply voltage is optimal. When the timing margin indicates that there is slack, the software may decide to lower the supply voltage to save power. Conversely, when the timing margins are tight or indicate potential timing violations, the software may increase the supply voltage to ensure reliable operation.

Based on the analysis, the software may send, via processor(s) (not shown) of system 100, control signals to adjust the supply voltage. System 100 hardware components, including the voltage regulators, may respond to such control signals to modify the supply voltage accordingly.

The dynamic adjustment of the supply voltage based on real-time timing margin measurements may allow the circuit to operate at the minimum possible voltage that still meets performance. Such optimization may reduce power consumption without compromising the IC's reliability. By monitoring and adjusting the supply voltage, the DVS mechanism of system 100 may ensure that the IC adapts to changing conditions, such as variations in workload, temperature, and process changes.

The DVS functionality facilitates the reliability and performance of the IC. By using real-time data from the critical path circuit, system 100 may determine voltage adjustments, balancing power savings with reliable operation. The use of a replica critical path 114 may allow for safe testing and calibration, ensuring that voltage adjustments are based on accurate and representative data. The combination of precise hardware measurements and responsive software control allows the critical path circuit to maintain optimal performance under varying conditions. The integration of DVS functionality within the critical path circuit allows the IC to operate efficiently, providing the necessary performance while minimizing power consumption.

### In-Situ Monitoring

In some examples, system 100 includes in-situ monitoring functionality, which may be used for real-time observation and analysis of an IC's performance. By directly monitoring the critical paths (e.g., real critical path 104 and replica critical path 114) within the operational environment of a SoC, in-situ monitoring allows the adjustments to the system to be made based on accurate and current data. In-situ monitoring enhances the reliability and efficiency of the integrated circuit by providing immediate feedback on performance metrics, allowing for dynamic adjustments to timing and voltage parameters.

The in-situ monitoring capabilities of the circuit, as depicted in FIG. 1A and FIG. 1B, may provide a robust mechanism for real-time observation and adjustment. By using feedback from the capture flip-flops, programmable delay elements, and other components, adjustments may be based on accurate and current data. This real-time monitoring may enhance the reliability and efficiency of the IC, enabling it to operate at optimal performance while minimizing power consumption. In some examples, in-situ monitoring capabilities of system 100 may be facilitated by components as illustrated in FIG. 1A and FIG. 1B. Such components may capture, process, and analyze data in real-time, providing a detailed view of the critical path performance.

In some examples, CFFs 118, 120, 122, 124, 126 may be placed along the critical path to capture the state of signals at various points. By recording the data in real-time, CFFs may provide immediate data about timing margins and signal propagation delays. For example, flip-flops may capture a progressively delayed version of the signal, offering a granular view of how delays impact the critical path (e.g., 104). Such data may identify potential timing issues and make adjustments.

Programmable delay element 110 may introduce controlled delays into the signal path, allowing for the simulation of different operational conditions. This allows the circuit to measure the effect of various delays on the critical path in real-time. By adjusting the delay settings dynamically, the system may observe how different timing scenarios impact the overall performance, providing valuable data for optimization.

The real critical path 104 may be the actual operational path within the IC, while the replica critical path 114 may mimic this path for testing and calibration purposes. In-situ monitoring may involve observing the real critical path 104 and the replica critical path 114 to ensure accurate performance data. The ability to switch between the real critical path 104 and the replica critical path 114 allows for monitoring without disrupting operations so that the data remains up-to-date.

The captured data from the flip-flops and delay elements may be processed and analyzed to determine the current state of the real critical path 104. The integration of hardware and software loops facilitates this operation.

XOR gate 132 may combine the outputs of the capture flip-flops to generate a signal that indicates the overall status of the captured data. The multiplexer 135 may then select between this combined signal and the output of the D flip-flop 137, based on the operational mode. Such processed signal may provide a consolidated view of the critical path performance, highlighting any potential timing issues.

D flip-flop 136 may store the processed signal, generating a path failure signature that may provide the current status of the critical path. The path failure signature provides a metric for performance and reliability, and may be used by the software to make informed decisions about adjustments. In some examples, the stored data may be maintained in a sticky status register so that the information remains available for long-term observation and analysis.

CDC handshake 138 and sync components (e.g., reset sync 144 and CDC sync 146) may facilitate reliable communication and synchronization across different clock domains. By managing the timing and status updates, CDC handshake 138 and sync components (e.g., reset sync 144, CDC sync 146) may maintain the integrity of the data used for in-situ monitoring. The CDC handshake may facilitate the transfer of data between the hardware and software components, enabling seamless integration and real-time analysis.

The in-situ monitoring capabilities of the circuit may enhance the reliability and efficiency of the system. By providing real-time observation and immediate feedback, system 100 may dynamically adjust system 100 parameters to optimize performance, for example, via DVS functionality. The real-time data captured by the in-situ monitoring components allows adjustments to be based on accurate and current information. The immediate feedback loop allows for precise tuning of timing margins and supply voltage, tailored to the current operational conditions.

The ability to observe and analyze critical path performance in real-time allows the system to make dynamic adjustments to the supply voltage and timing parameters. This flexibility allows the IC to operate at optimal efficiency, minimizing power consumption while maintaining performance and reliability. Moreover, monitoring and adjustment based on real-time data aids in preventing timing violations and other performance issues that may compromise the reliability of the IC. By addressing potential problems as they arise, system 100 may maintain stable and reliable operation.

### Failure Signature Analysis

As depicted in FIGS. 1A-1B, failure signature analysis may facilitate the detection of timing failures and the interpretation of these failures to provide reliable operation of the integrated circuit (IC) and prevent further timing violations. Such analysis uses delayed capture flip-flops to monitor signal propagation along critical paths and generate failure signatures that indicate timing issues. These signatures are utilized for DVS and other adaptive measures to maintain the IC's performance and reliability. FIG. 1A and FIG. 1B illustrate the hardware components and their interactions in performing this analysis. By generating and analyzing failure signatures, system 100 may dynamically adjust supply voltage and other parameters to maintain optimal performance and reliability. The detailed processing and storage of failure signatures allows the IC to operate efficiently under varying conditions, providing a robust and adaptable solution for modern semiconductor design.

Failure signatures indicate the presence and severity of timing violations in the critical path (e.g., real critical path 104 or replica critical path 114). These signatures highlight areas where the signal timing does not meet the margins, allowing for targeted corrective actions. Moreover, the failure signatures inform the software loop about the current timing margins. Based on this data, the software may adjust the supply voltage dynamically to ensure optimal performance and power consumption. By continuously monitoring and interpreting failure signatures, the system may optimize the timing and performance of the IC. This ongoing analysis ensures that the IC operates within safe and efficient parameters, adapting to changes in workload, temperature, and process variations. Failure signatures provide a long-term record of the critical path performance, allowing for the identification of trends and potential degradation over time. This historical data may be used for predictive maintenance for the long-term reliability of the IC.

Detecting Path Failures with Delayed Capture Flops

Delayed capture flip-flops may detect path failures by introducing intentional delays and observing their effects on signal timing. This method provides a granular view of how signals propagate through the critical path under various conditions. In some examples, a method for detecting path failures may include initializing programmable delay element 110 to introduce a specific delay into the signal path. The signal may travel through the critical path, and the state of the signal may be captured at various points by the CFFs 118, 120, 122, 124, 126. The CFFs 118, 120, 122, 124, 126 may record the delayed signal states, providing data on how the delay affects the timing.

The captured states from the delayed flip-flops may be compared to the expected signal states. Discrepancies may indicate a timing failure in the critical path. Failure signatures may be generated from the comparison of the delayed and expected signal states. These signatures provide information about the timing performance of the critical path and may be used to identify and rectify timing issues.

For example, in some examples, XOR gate 132 may combine the outputs of the capture flip-flops to produce a signal indicating the overall status of the captured data. Multiplexer 135 may select between the combined signal from the XOR gate 132 and the output of the D flip-flop 137, based on the operational mode. D Flip-Flop 137 may store the failure signature, providing a stable and persistent indication of timing failures. In some examples, such signature may be stored in a sticky status register so that the signature remains available for long-term observation and analysis.

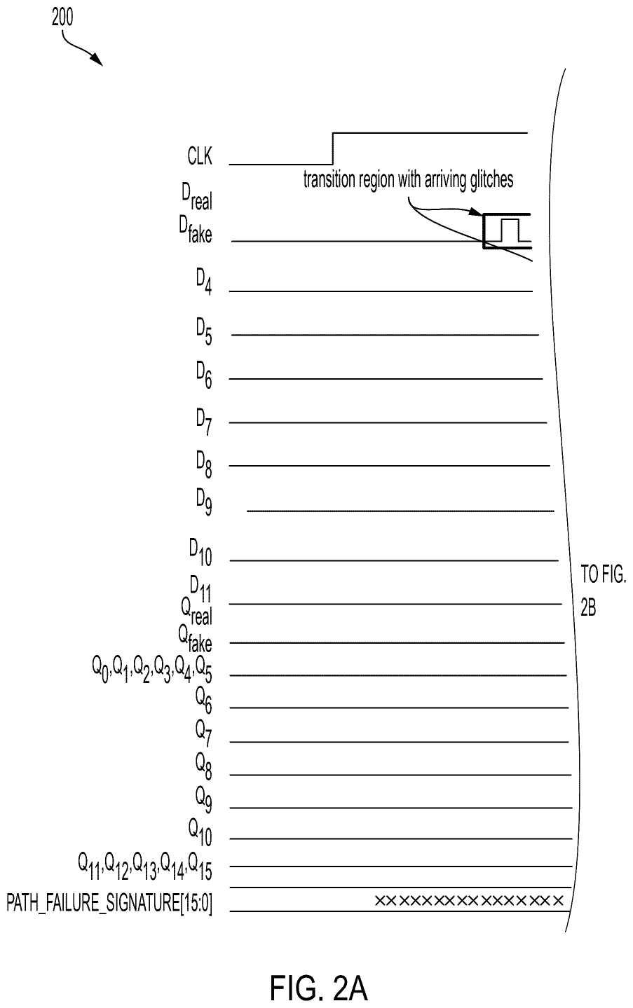

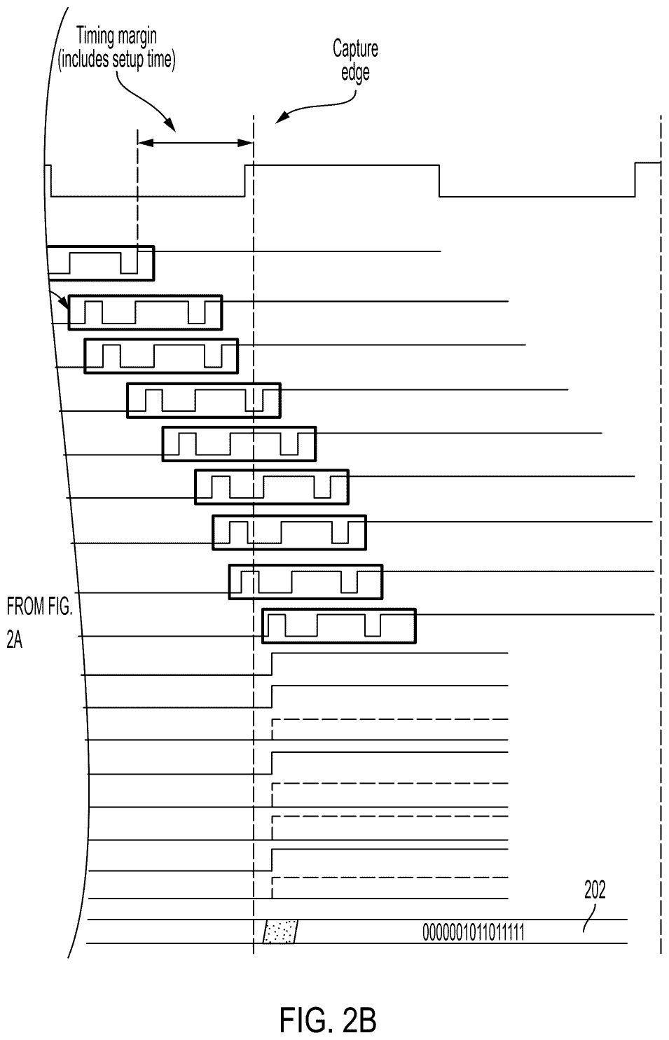

FIGS. 2A-2B depict a timing diagram 200 for an operation of system 100. Diagram 200 may provide a visual representation of signal transitions and may capture the critical path circuit, corresponding to the components and functionalities described in FIGS. 1A-1B. Diagram 200 illustrates the timing margins, capture edges, and the generation of the path failure signature, highlighting how system 100 detects and analyzes timing failures.

As shown in FIGS. 2A-2B, diagram 200 includes various signal lines representing the propagation of data through the critical path. The signals shown include the clock (CLK), the real data (D_real), the fake data (D_fake), and multiple delayed data signals (D_4 to D_11). Diagram 200 further illustrates the outputs of the capture flip-flops (Q_real, Q_fake) and the final path failure signature (PATH_FAILURE_SIGNATURE [15:0]).

The CLK signal may be the reference clock that synchronizes the operations of the capture flip-flops and other components in the critical path circuit. CLK provides the timing reference for capturing the data transitions. D_real may be the actual data propagating through the real critical path (104 in FIG. 1A) and D_fake may be the data in the replica critical path (114 in FIG. 1A) used for testing and calibration. Delayed Data Signals (D_4 to D_11) may be the data states at various points along the critical path, delayed by different amounts using the programmable delay element (110 in FIG. 1A). These delays simulate different timing conditions to measure the timing margins.

Diagram 200 highlights the concept of timing margins and capture edges, which may be used to detect and analyze timing failures. The timing margin may be the time window within which the data is to be stable before the clock edge to be correctly captured by the flip-flops. Such window includes the setup time used for reliable data capture. Diagram 200 shows the transition region with arriving glitches, indicating the period during which the data signals stabilize before the capture edge. The capture edge may be the point in time when the clock signal triggers the flip-flops to capture the data state. The capture edge may determine whether the data has been correctly latched by the flip-flops. In diagram 200, the capture edge is marked by the rising edge of the CLK signal, aligning with the stable data period.

As discussed above, path failure signature may be generated based on the comparison of captured data states from no-delay and delayed captures. Diagram 200 shows how the captured data from the flip-flops may be used to form the path failure signature. For example, Q_real may be the output of the flip-flop capturing the real data (capture flip-flop 106 in FIG. 1A). Q_fake may be the output of the flip-flop capturing the fake data after being processed through the replica critical path and delayed by the programmable delay element.

Delayed Capture Flip-Flops (Q₀ to Qₙ₋₁) outputs may be the states of the data captured by the delayed capture flip-flops (118, 120, 122, 124, 126 in FIG. 1A). The outputs (Q₀, Q₁, Q₂ . . . , Qₙ₋₂, Qₙ₋₁) may correspond to different delay settings, providing a detailed view of the timing margins. Path Failure Signature (PATH_FAILURE_SIGNATURE [15:0] may be formed by combining the outputs of the delayed capture flip-flops and indicating whether the data was captured correctly within the timing margins. The lower portion of the timing diagram shows the path failure signature bits 202, where ‘l’ indicates a failure (timing violation) and ‘0’ indicates correct data capture.

Thus, diagram 200 provides a detailed visual analysis of how the critical path circuit may operate in real-time to detect and analyze timing failures. By comparing the no-delay and delayed captures, circuits 101, 103 may identify when the data does not meet the timing margins. This may prevent timing-related errors in the IC. The transition region with arriving glitches highlights areas where timing violations are likely to occur, providing a focus for analysis. Diagram 200 shows how different delay settings affect the timing margins. This information may be used to dynamically adjust the supply voltage and other parameters to optimize performance and reliability. The continuous monitoring and adjustment based on real-time data allow the IC to operate within safe and efficient parameters. System 100 software may read the path failure signature and capture data to analyze the timing margins. Based on this analysis, system 100 may make real-time adjustments to the supply voltage and delay settings.

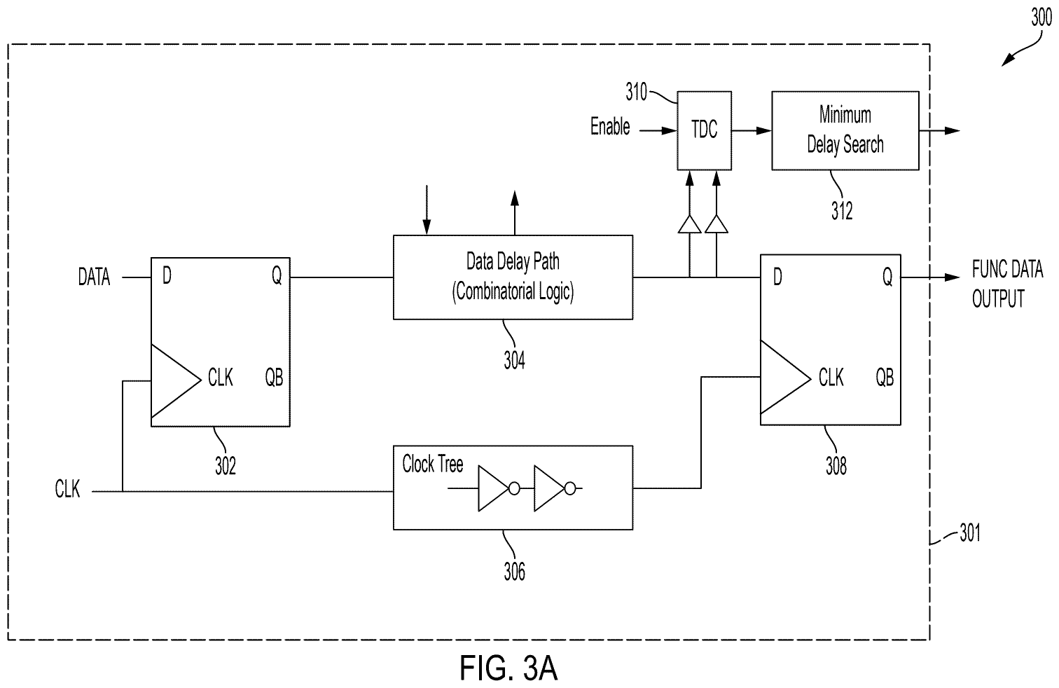

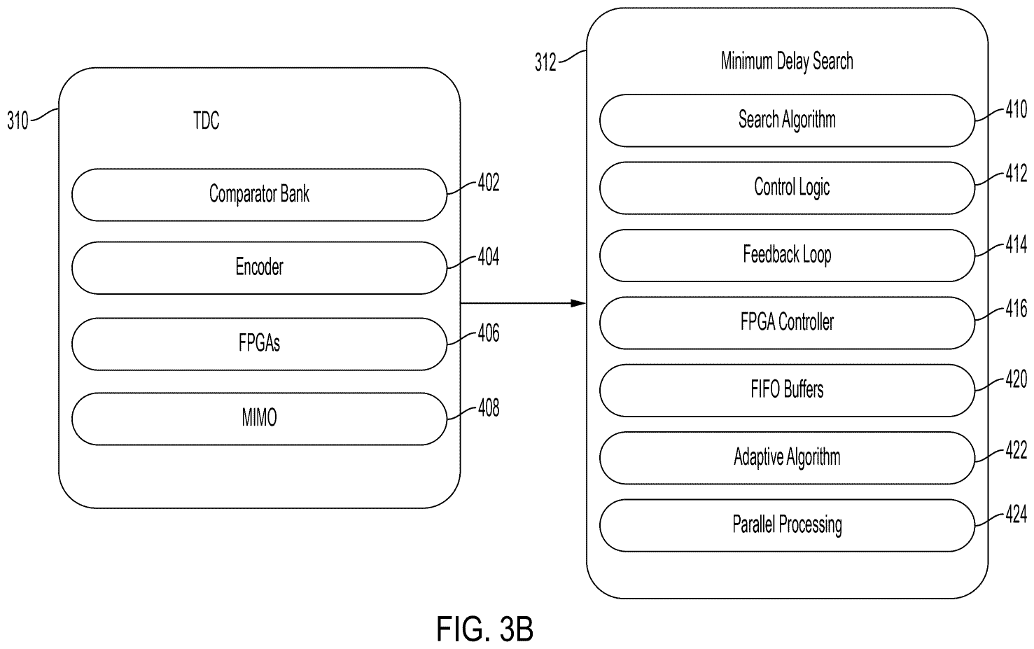

FIGS. 3A-3B illustrate a critical path monitoring system 300 (“system 300”). As shown in FIG. 3A, in some examples, system 300 may include an IC or SoC (e.g., ckt 301) including data flip-flop 302, data delay path 304, clock tree 306, output flip-flop 308, TDC 310, and/or minimum delay search (MDS) 312. System 300 may measure margin and optimize such timing delays in an integrated circuit (IC). System 300 may implement TDC 310 and a MDS 312 to facilitate precise monitoring and dynamic adjustments of critical paths. Components (e.g., 302-312) within circuit 301 provide a specific role in capturing, analyzing, and adjusting the timing data.

In some examples, data flip-flop 302 may receive the DATA and CLK inputs and capture the data at the rising or falling edge of the clock signal, providing a synchronized data output (Q) and the corresponding complement (QB). The clock tree 306 may distribute the CLK signal to various components within the system, providing for synchronized operation and minimal clock skew. For example, CLK signal may be output to the data flip-flops (302 and 308) so that data capture and processing occur at precise intervals.

The captured data (Q) may be output to data delay path 304, initiating the delay measurement process. Data delay path 304 may include combinatorial logic that may process the input data, introducing a controlled delay. The output signal of data delay path 304 may be used for determining the timing margin. For example, output signal of data delay path 304 may be used to evaluate the performance of the critical path in data delay path 304, which may be analyzed by the TDC 310 and Minimum Delay Search 312.

In some examples, output flip-flop 308 may capture the output of data delay path 304 at the clock edge, providing a synchronized output (Q) and complement (QB). The captured output (Q) may be compared with the input data to determine the delay introduced by the Data Delay Path, which may be used for timing margin analysis.

In some examples, TDC 310 may convert the time delay between signal transitions into a digital value. TDC 310 may operate with high precision, for example with granularity in picoseconds. By measuring the delay introduced by data delay path 304, TDC 310 may provide the data to assess the timing margins, and allow system 300 to detect minute delays that may affect performance.

In some examples, MDS 312 may perform a search to find the smallest delay that may meet system 300's timing margins. For example, MDS 312 may use one or more algorithms to adjust the delay settings dynamically. Implementing MDS 312 allows system 300 to operate at optimal performance by fine-tuning the delay settings based on real-time data from TDC 310. MDS 312 may aid in in maintaining a balance between performance and power efficiency.

FIG. 3B depicts the time-to-digital converter (TDC) and the minimum delay search of system 300, in accordance with some examples. Flash TDC 310 may include comparator bank 402, encoder 404, field-programmable gate arrays (FPGAs) 406, MIMO 408. In some examples, MDS 312 may include search algorithm 410, control logic 412, feedback loop 414, FPGA controller 416, first-in first-out (FIFO) buffer(s) 420, adaptive algorithm 422, and/or parallel processing 424.

TDC 310 converts the timing delay between signal transitions into a digital value. This conversion may be used to measure the timing margins and make real-time adjustments to the IC's operating conditions. Comparator bank 402 may include a bank of parallel comparators that may simultaneously sample the input signal and compare such input against reference levels (e.g., SOFTMAX). The comparators may be responsible for a specific time bin, allowing TDC 312 to convert the input time delay into a digital code word with minimal latency. The output of the comparators may be fed into an encoder, which may convert the code from the comparators into a binary code representing the time delay.

In some examples, flash TDC 310 may be implemented on FPGAs to take advantage of their configurability and parallel processing capabilities. FPGAs 406 may host multiple TDC channels, which may be dedicated to different critical paths, providing a scalable solution for complex ICs. In some examples, multiple input multiple output (MIMO) 408 and FIFO buffers 420 may be used to manage the data flow between various TDCs and the subsequent processing stages. MIMO 408 buffers may handle multiple data streams simultaneously, while FIFO buffers 420 may provide for orderly processing and reduced latency. As mentioned above, TDC 310 may achieve resolutions down to a 10 picoseconds, making such hardware suitable for high-speed applications. The precision may be determined by the number of comparators and the reference levels used.

In some examples, MDS 312 may be responsible for identifying the smallest possible delay that meets the timing margins (i.e., SOFTMAX). MDS 312 may allow the IC to operate at optimal performance levels without unnecessary power consumption. In some examples, search algorithm 410 may include a binary or linear search algorithm to determine the smallest delay that does not cause timing violations. Such algorithm may iteratively adjust the delay introduced by a programmable delay element and monitor the timing margins.

In some examples, control logic 412 may manage the search process, adjust the delay settings, and read the output from the TDC. Control logic 412 may provide that the delay is fine-tuned to achieve the best possible performance. For example, feedback loop 414 may monitor the timing margins and update the delay settings in real-time. Feedback loop 414 may allow the system to adapt to changing conditions such as temperature variations or process changes. Moreover, implementing the control logic on an FPGA controller 416 may provide flexibility and scalability. FPGA controller 416 may dynamically reconfigure the search parameters and adjust the delay settings based on real-time data from the TDC.

In some examples, FIFO buffers 420 may store intermediate results during the search process so that the control logic has immediate access to the data for making adjustments. In some examples, adaptive algorithm 422 may learn from past data to predict the optimal delay settings more quickly. This approach may reduce the time for calibration and improve the system's overall efficiency. Parallel Processing 424 may facilitate parallel processing capabilities of FPGAs, in which multiple delay searches may be conducted simultaneously for different critical paths, further enhancing system 300's performance.

The TDC and minimum delay search components may be used for the high-precision, real-time monitoring, and adjustment of critical path delays in integrated circuits. The flash TDC, with corresponding bank of comparators and high-resolution capabilities, may provide accurate timing measurements used for optimizing IC performance. The minimum delay search, equipped with advanced search algorithms and control logic, may ensure that the IC operates within its optimal timing margins while minimizing power consumption. Implementing these components using FPGAs and advanced buffering techniques like MIMO 408 and FIFO buffers 420 allows for scalable, flexible, and highly efficient critical path monitoring systems suitable for modern high-speed analog and mixed-signal circuits

### Optimizing Granularity

In some examples, the precision level of the TDC 310 may directly impact the accuracy and performance of the critical path monitoring system. Choosing the appropriate precision involves balancing the need for high resolution with the constraints of power consumption and computational overhead. For example, selecting a coarse precision level may lead to significant drops in accuracy. This is due to the inability of the TDC 310, which includes a comparator bank 402 and encoder 404, to precisely measure and convert small time delays into digital values. The reduced granularity in the time-to-digital conversion may result in timing margin calculations that do not accurately reflect the true performance of the IC.

However, in many scenarios, even lower precision levels may be acceptable without impacting the system's performance. For example, in some examples, system 300 may operate effectively with a reduced precision when the timing margins are sufficiently large, allowing for minor variations without causing functional failures. The adaptability of system 300, supported by the control logic 412 and feedback loop 414 within MDS 312, allows system 300 to dynamically adjust to varying precision levels based on real-time data.

System 300 may, in some examples, implement deferred precision, which involves initially operating the TDC 310 with a lower precision and increasing the precision when increased precision is useful. Such method conserves power and computational resources by avoiding the use of maximum precision.

In some examples, system 300 may implement a softmax function, which may act like a multidimensional sigmoid, and may be used to determine when increased precision is used. The softmax outputs may be analyzed to assess whether the current precision level is sufficient. When the outputs indicate a proximity to a threshold where accuracy might degrade, the system, using the FPGA Controller 416, may increase the precision to maintain performance.

In some examples, because timing errors exhibit a statistical distribution, system 300 may set a comfortable probability level for such errors. For example, search algorithm 410 within the MDS 312 may identify acceptable timing margins that accommodate common errors while disregarding rare events that may have minimal impact on performance.

In some examples, system 300 may set arbitrary probability settings. For example, by setting arbitrary probability thresholds that system is comfortable with, the control logic allows the performance to be maintained without unnecessary power consumption. When the probability of timing errors remains within such threshold, system 300 may operate efficiently with the current precision settings.

To support such precision, in some examples, system 300 architecture involves multiple multiply-accumulate stages. These stages may perform extensive calculations, feeding their outputs into a softmax function to determine the system's operational state. In some examples, softmax outputs, or the outputs from the multiply-accumulate stages, may be processed by the softmax function, which may serve as a threshold detector. This function may help in determining the precision level used for accurate calculations and performance maintenance.

### Threshold Detection Using Sigmoid and Boltzmann Functions

In some examples, threshold detection may be performed using sigmoid or Boltzmann functions. These functions may provide a sharp transition at the threshold, allowing the system to detect when precision adjustments are useful. Thus, in some examples, when the system operates far from the threshold, lower precision levels may be tolerated without a significant loss in accuracy. The adaptive algorithm within the MDS 312 may monitor precision levels, ensuring optimal performance.

In some examples, based on power saving consideration, precision may be gradually degraded until performance starts to be affected. The adaptive algorithm and feedback loop in the Minimum Delay Search 312 measure the impact on system 300's accuracy and may make adjustments to maintain efficiency. By reducing precision levels when higher accuracy is not needed, system 300 may achieve power savings. For example, in some examples, reducing the precision of the TDC 310 may save up to 75% of the power consumed by the multiplier stages.

### Application to BPSK Systems

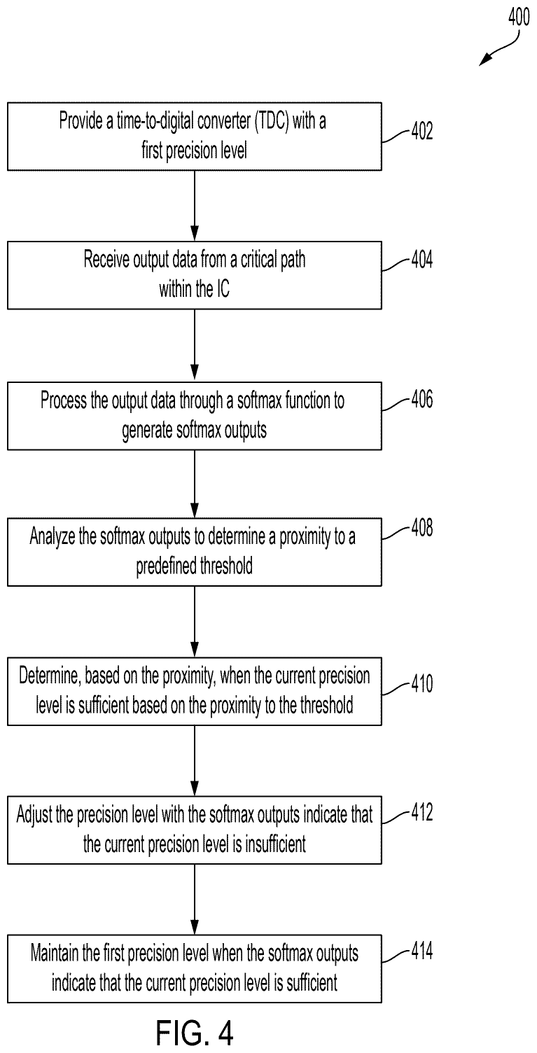

Referring now to FIG. 4, in some examples, a method 450 of deferred precision may be applied to systems like Binary Phase Shift Keying (BPSK). For example, when noise levels are low, system 300 may tolerate more errors, allowing for lower supply voltages and currents. In some examples, system 300 starts with lower voltage settings and monitors the softmax outputs, as depicted in FIG. 4. When or if the outputs indicate potential accuracy degradation, system 300 raises the voltage to maintain performance, leveraging the FPGA-based control logic.

In operation 452, the method may include providing a TDC with a first precision level. In operation 454, the method may include receiving output data from a critical path within the IC. In operation 456, the method may include processing the output data through a softmax function to generate softmax outputs. In operation 458, the method may include analyzing the softmax outputs to determine a proximity to a predefined threshold. In operation 460, the method may include determining, based on the proximity, when the current precision level is sufficient based on the proximity to the threshold. In operation 462, the method may include adjusting the precision level when the softmax outputs indicate that the current precision level is insufficient. In operation 464, the method may include maintaining the first precision level when the softmax outputs indicate that the current precision level is sufficient.

In some examples, replica circuits (e.g., 114) provide advantageous information about system performance. Replica circuits may be degraded to predict the behavior of the actual or real system, ensuring reliability and allowing for managing temporary accuracy degradations. For example, in some examples, system 300 determines whether temporary accuracy degradations are acceptable for the application, using data from the replica circuits (e.g., 114) to make informed decisions.

In some examples, system 300 may implement dynamic adjustments to the supply voltage and current based on real-time data. Dynamic supply voltage adjustments may provide for optimal performance and power efficiency. In some examples, system 300 provides that MSBs settle before re-running calculations. This approach may avoid unnecessary power consumption by focusing on the relevant data. In some examples, the system builds and maintains margins to prevent functional problems. The control logic may act before issues arise, providing for stable operation.

Thus, the foregoing features of the TDC-based critical path monitoring system, including deferred precision and dynamic adjustments, enhance system adaptability and efficiency. By leveraging real-time data and sophisticated algorithms, system 300 balances power consumption and performance, ensuring reliability under varying operational conditions.

In the examples herein, system 100, 300 components (e.g., 102-146, and/or 302-312) may include a number of processing units and/or CPUs. One or more aspects or features of the subject matter described herein may be realized in digital electronic circuitry, integrated circuitry, specially designed ASICs, field programmable gate arrays (FPGAs) computer hardware, firmware, software, and/or combinations thereof. These various aspects or features may include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and typically interact through a communication network. The relationship of client and server arises by virtue of computer programs running on the respective computers and having a client-server relationship to each other.

These computer programs, which can also be referred to programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” (or “computer readable medium”) refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” (or “computer readable signal”) refers to any signal used to provide non-transitory machine readable instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device (not shown), such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including, but not limited to, acoustic, speech, or tactile input. Other possible input devices include, but are not limited to, touch screens or other touch-sensitive devices such as single or multi-point resistive or capacitive trackpads, voice recognition hardware and software, optical scanners, optical pointers, digital image capture devices and associated interpretation software, and the like.

The examples described herein may be embodied in systems, apparatus, methods, computer programs and/or articles depending on the desired configuration. Any methods or the logic flows depicted in the accompanying figures and/or described herein do not necessarily require the particular order shown, or sequential order, to achieve desirable results. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. The implementations described above can be directed to various combinations and subcombinations of the disclosed features and/or combinations and subcombinations of further features noted above. Furthermore, above described advantages are not intended to limit the application of any issued claims to processes and structures accomplishing any or all of the advantages. Furthermore, any reference to this disclosure in general or use of the word “example” in the singular is not intended to imply any limitation on the scope of the claims set forth below. Multiple examples may be set forth according to the limitations of the multiple claims issuing from this disclosure, and such claims accordingly define the example(s) herein, and their equivalents, that are protected thereby.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical and preferred examples, it is to be understood that such detail is solely for that purpose and that the disclosure is not limited to the expressly disclosed examples, but, on the contrary, is intended to cover modifications and equivalent arrangements that are within the spirit and scope of the appended claims. For example, it is to be understood that the present disclosure contemplates that, to the extent possible, one or more features of any example can be combined with one or more features of any other example.

1. A system for critical path monitoring in an integrated circuit (IC), comprising:
a data flip-flop operable to: receive a data input and a clock input, and generate a first data output and a first clock output;
a data delay path coupled to the data flip-flop to receive the first data output and the first clock output, and generate a delayed data output;
an output flip-flop, coupled to the data delay path to receive the delayed data output and the first clock output, and generate a second data output and a second clock output; a time-to-digital converter (TDC), coupled to the data delay path, comprising:
a comparator bank operable to compare the delayed data output against reference levels and generate a code;
an encoder, coupled to the comparator bank, operable to convert the code into a binary code representing a time delay;
one or more field programmable gate arrays (FPGAs) operable to host multiple TDC channels for parallel processing;
one or more multiple output (MIMO) buffers operable to process multiple data streams and manage data flow between TDC channels and subsequent processing stages;
a minimum delay search coupled to the TDC;
a control circuit, coupled to the minimum delay search, operable to dynamically adjust a supply voltage based on timing margins and delay settings identified by the minimum delay search; and
a software loop, operable to read the output from the minimum delay search, analyze the timing margins, and control the control circuit to maintain optimal performance and power consumption of the IC.

2. The system of claim 1, wherein the data flip-flop and the output flip-flop are operable to synchronize the data input and output with the clock signal to facilitate accurate timing measurements.

3. The system of claim 1, wherein the data delay path includes adjustable delay elements to fine-tune the delay introduced to the data signal.

4. The system of claim 1, wherein the comparator bank within the TDC includes a plurality of comparators operable to compare the delayed data output against a specific reference level.

5. The system of claim 1, wherein the encoder within the TDC converts the code from the comparator bank into a binary code representing a measured time delay.

6. The system of claim 1, wherein the FPGAs are operable to reprogram the TDC channels dynamically to handle different critical paths within the IC.

7. The system of claim 1, wherein the MIMO buffers are operable to manage multiple data streams simultaneously, ensuring efficient data flow between the TDC and subsequent processing stages.

8. The system of claim 1, wherein a search algorithm within the minimum delay search employs a binary search technique to converge on optimal delay settings.

9. The system of claim 1, wherein control logic is implemented using an FPGA controller to dynamically adjust delay settings based on real-time data from the TDC.

10. The system of claim 1, wherein the minimum delay search further comprises:
a search algorithm operable to iteratively adjust the delay introduced by the data delay path and monitor the timing margins to identify the smallest possible delay that meets timing margins;
control logic operable to manage a search process by adjusting delay settings and reading the output from the TDC;
a feedback loop operable to monitor the timing margins and update delay settings in real-time based on changes in process, voltage, and temperature conditions;
a FPGA controller operable to dynamically reconfigure search parameters and adjust delay settings based on real-time data from the TDC;
one or more FIFO buffers operable to store intermediate results during the search process to facilitate immediate access to data operable to perform adjustments;
an adaptive algorithm operable to learn from past data to predict optimal delay settings and reduce calibration time; and
a parallel processing controller operable to conduct multiple delay searches simultaneously for different critical paths.

11. A method for dynamically adjusting precision in an integrated circuit (IC) monitoring system, comprising:
providing a time-to-digital converter (TDC) with a first precision level;
receiving output data from a critical path within the IC;
processing the output data through a softmax function to generate softmax outputs;
analyzing the softmax outputs to determine a proximity to a predefined threshold;
determining, based on the proximity, when a current precision level is sufficient based on the proximity to the threshold;
adjusting the precision level when the softmax outputs indicate that the current precision level is insufficient; and
maintaining the first precision level when the softmax outputs indicate that the current precision level is sufficient.

12. The method of claim 11, further comprising measuring timing delays in the critical path using a comparator bank and an encoder.

13. The method of claim 12, wherein the TDC comprises the comparator bank and the encoder, wherein the timing delays are measured by comparing a delayed data output against reference levels using the comparator bank and converting the comparisons into a binary code using the encoder.

14. The method of claim 12, further comprising adjusting a supply voltage of the IC based on the softmax outputs to maintain optimal timing margins, determined by control logic and feedback loop 414 in the Minimum Delay Search 312.

15. The method of claim 11, further comprising implementing the TDC on a Field-Programmable Gate Array (FPGA) for parallel processing.

16. The method of claim 11, further comprising implementing one or more MIMO buffers to manage the data flow between the TDC and one or more processing stages.

17. The method of claim 11, wherein the softmax function acts as a multidimensional sigmoid to analyze the output data and determine a precision level.

18. The method of claim 11, further comprising adjusting delay settings dynamically based on real-time data to optimize timing margins, using a search algorithm and control logic in the minimum delay search.

19. The method of claim 11, further comprising storing intermediate results during a precision adjustment process using one or more FIFO buffers.

20. The method of claim 11, further comprising implementing an adaptive algorithm operable to learn from past data to predict optimal precision settings and reduce calibration time.
